(19) United States
(12) Patent Application Publication
(10) Pub. No.: US 2026/0180590 A1
(43) Pub. Date: Jun. 25, 2026

(54) ANALOG-TO-DIGITAL CONVERTER AND METHOD FOR CALIBRATING COMPARATOR WITHIN ANALOG-TO-DIGITAL CONVERTER

(71) Applicant: Realtek Semiconductor Corp., HsinChu (TW)

(72) Inventor: Wei-Cian Hong, HsinChu (TW)

(73) Assignee: Realtek Semiconductor Corp., HsinChu (TW)

(21) Appl. No.: 19/425,994

(22) Filed: Dec. 18, 2025

(30) Foreign Application Priority Data
Dec. 24, 2024 (TW) 113150386

(51) Int. Cl. H03M 1/10

(52) U.S. Cl. CPC H03M 1/1023

(57) ABSTRACT

An analog-to-digital converter (ADC) and a method for calibrating a comparator within the ADC are provided. The ADC includes a sampling capacitor array, the comparator, an offset calibration control switch and a control logic, where the offset calibration control switch is coupled between the sampling capacitor array and the comparator. In a sampling phase, the sampling capacitor array samples an input signal, the offset calibration control switch is turned off, input terminals of the comparator are pulled to a same level, and the control logic performs calibration of the comparator according to a comparison result generated by the comparator. In a conversion phase, the offset calibration control switch is turned on, and the control logic output an analog-to-digital conversion result of the input signal according to the comparison result.

### BACKGROUND OF THE INVENTION

### 1. Field of the Invention

The present invention is related to calibration of comparators, and more particularly, to an analog-to-digital converter (ADC) and a method for calibrating a comparator within the ADC.

### 2. Description of the Prior Art

Accuracy of a comparator within an analog-to-digital converter (ADC) is one of critical factors affecting performance of the ADC. However, the comparator typically has an offset, which is likely to lead to erroneous comparison results when input signals are very close. In some related arts, the ADC does not immediately start the task of analog-to-digital conversion after power-on, but first performs comparator offset calibration to ensure that the ADC operates with a sufficiently small offset. Furthermore, the comparator offset typically needs to be periodically calibrated to ensure that the comparator can properly operate even if temperature changes. Thus, the analog-to-digital conversion operation needs to be periodically paused for the aforementioned comparator calibration.

In some related arts, a specific period within a working cycle can be allocated to comparator calibration in the ADC to prevent the ADC from being forced to suspend due to comparator calibration. However, this approach limits a sampling frequency of the ADC, which prevents operation speed from being increased.

Thus, there is a need for a novel architecture and an associated method, which can perform calibration of the comparator without introducing any side effect or in a way that is less likely to introduce side effects.

### SUMMARY OF THE INVENTION

An objective of the present invention is to provide an analog-to-digital converter (ADC) and a method for calibrating a comparator within the ADC) in order to prevent the calibration of the comparator from resulting in task suspense or operation frequency limit of the ADC.

At least one embodiment of the present invention provides an analog-to-digital converter (ADC). The ADC comprises a sampling capacitor array, a comparator, an offset calibration control switch and a control logic, where the offset calibration control switch is coupled between the sampling capacitor array and the comparator, and the control logic is coupled to the comparator. The sampling capacitor array is configured to sample an input signal, and the comparator is configured to output a comparison result according to voltage levels on a first input terminal and a second input terminal of the comparator. In a sampling phase of the ADC, the offset calibration control switch is turned off to prevent the first input terminal and the second input terminal of the comparator from being coupled to the sampling capacitor array, the first input terminal and the second input terminal of the comparator are pulled to a same level, and the control logic performs calibration of the comparator according to the comparison result. In a conversion phase of the ADC, the offset calibration control switch is turned on to make the first input terminal and the second input terminal of the comparator be coupled to the sampling capacitor array, and the control logic outputs an analog-to-digital conversion result of the input signal according to the comparison result.

At least one embodiment of the present invention provides a method for calibrating a comparator within an ADC. The method comprises: in a sampling phase of the ADC, turning off an offset calibration control switch coupled between a sampling capacitor array and the comparator, to prevent a first input terminal and a second input terminal of the comparator from being coupled to the sampling capacitor array; in the sampling phase, pulling the first input terminal and the second input terminal of the comparator to a same level, in order to perform calibration of the comparator according to a comparison result output from the comparator; in a conversion phase of the ADC, turning on the offset calibration control switch to make the first input terminal and the second input terminal of the comparator be coupled to the sampling capacitor array; and in the conversion phase, outputting an analog-to-digital conversion result of the input signal according to the comparison result.

The ADC and the method provided by the embodiments of the present invention can utilize the offset calibration control switch to isolate the sampling capacitor array and the comparator, enabling the comparator to be calibrated in the sampling phase. In comparison with performing calibration of the comparator in remaining time of the conversion phase, the method of the present invention which performs calibration in the sampling phase can prevent the task of the comparator from being suspended, and is not a main factor affecting the operation speed of the ADC. Thus, the present invention can solve the problem of the related art without introducing any side effect or in a way that is less likely to introduce side effects.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating an analog-to-digital converter (ADC) according to an embodiment of the present invention.

FIG. 2 is a diagram illustrating operation timing of the ADC shown in FIG. 1 according to an embodiment of the present invention.

FIG. 3 is a diagram illustrating an ADC according to an embodiment of the present invention.

FIG. 4 is a diagram illustrating operation timing of the ADC shown in FIG. 3 according to an embodiment of the present invention.

FIG. 5 is a diagram illustrating a comparator according to an embodiment of the present invention.

FIG. 6 is a diagram illustrating calibration of the comparator shown in FIG. 5 according to an embodiment of the present invention.

FIG. 7 is a diagram illustrating a comparator according to an embodiment of the present invention.

FIG. 8 is a diagram illustrating a working flow of a method for calibrating a comparator within an ADC according to an embodiment of the present invention.

### DETAILED DESCRIPTION

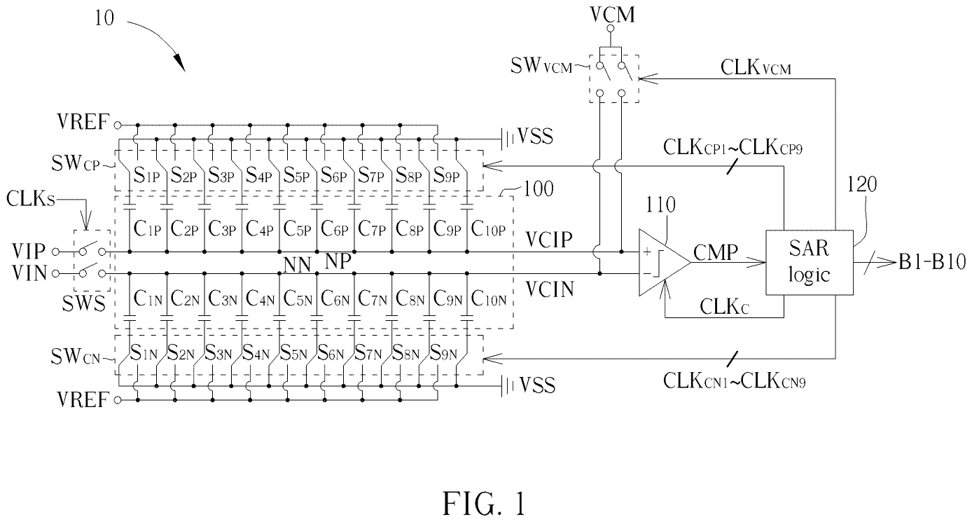

FIG. 1 is a diagram illustrating an analog-to-digital converter (ADC) such as a successive approximation register (SAR) ADC 10 according to an embodiment of the present invention. As shown in FIG. 1, the SAR ADC 10 may comprise a sampling capacitor array 100, a comparator 110, a control logic such as a SAR logic 120 (e.g. a SAR logic circuit), a sampling switch such as a switch SWS, a calibration voltage control switch such as a switch SW_{VCM}, and SAR control switches such as switches SW_{CP} and SW_{CN}. In this embodiment, an entirety of capacitors C_{1P}, C_{2P}, C_{3P}, C_{4P}, C_{5P}, C_{6P}, C_{7P}, C_{8P}, C_{9P} and C_{10P} (e.g. C_{1P}=2×C_{2P}=4×C_{3P}=8×C_{4P}=16×C_{5P}=32×C_{6P}=64×C_{7P}=128×C_{8P}=256×C_{9P}=512×C_{10P}) within the sampling capacitor array 100 may be regarded as a positive sampling capacitor coupled to a positive sampling node NP, and an entirety of capacitors C_{1N}, C_{2N}, C_{3N}, C_{4N}, C_{5N}, C_{6N}, C_{7N}, C_{8N}, C_{9N} and C_{10N} (e.g. C_{1N}=2×C_{2N}=4×C_{3N}=8×C_{4N}=16×C_{5N}=32×C_{6N}=64×C_{7N}=128×C_{8N}=256×C_{9N}=512×C_{10N}) within the sampling capacitor array 100 may be regarded as a negative sampling capacitor coupled to a negative sampling node NN.

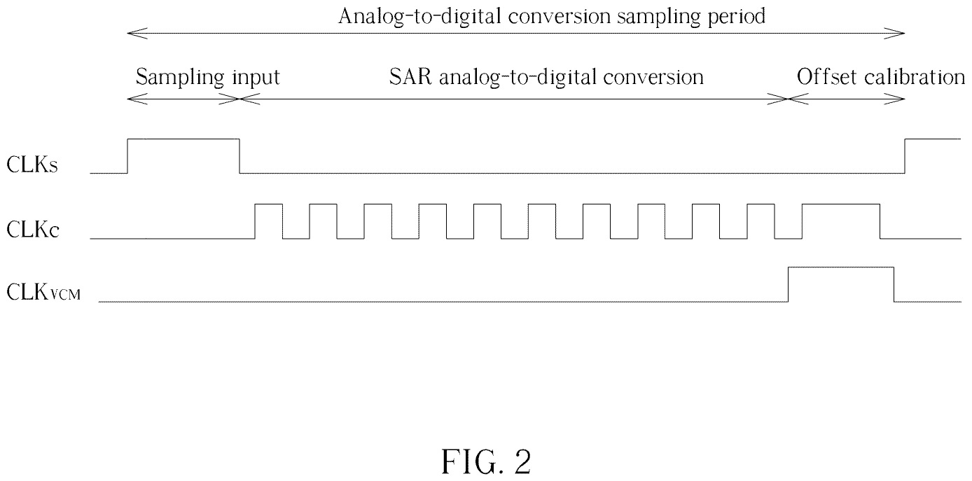

FIG. 2 is a diagram illustrating operation timing of the SAR ADC 10 shown in FIG. 1 according to an embodiment of the present invention, where a period of a control signal CLK_{S} may be regarded as a sampling period of the SAR ADC 10. In this embodiment, when the control signal CLK_{S} is at a high level (e.g. having a logic value “1”), the switch SWS may transmit input signals VIP and VIN to the positive sampling node NP and the negative sampling node NN, respectively, and sampling signals VCIP and VCIN respectively stored on the positive sampling capacitor and the negative sampling capacitor at this moment may be regarded as sampling results of the input signals VIP and VIN, where the input signals VIP and VIN may be a pair of differential signals. When the control signal CLK_{S} turns from the high level to a low level (e.g. turning from the logic value “1” to the logic value “0”), the SAR logic 120 may trigger the comparator 110 to start comparing the sampling signals VCIP and VCIN via the control signal CLK_{C} to generate a comparison result CMP, where the SAR logic 120 may control switches S_{1P}-S_{9P} within the switch SW_{CP} and switches S_{1N}-S_{9N} within the switch SW_{CN} via control signals CLK_{CP1}-CLK_{CP9} and CLK_{CN1}-CLK_{CN9} according to the comparison result CMP, in order to selectively switch any of the capacitors C_{1P}-C_{10P} and any of the capacitors C_{1N}-C_{9N} from a reference voltage VSS to a reference voltage VREF. After multiple times of comparison and corresponding switching, the SAR logic 120 may output digital outputs (e.g. bits B1 to B10) corresponding to the input signals {VIP, VIN} according to the comparison result CMP which is output after every comparison of the comparator 110.

For example, the comparator 110 may compare the sampling signals VCIP and VCIN at a first rising edge of the control signal CLK_{C} to generate a first value of the comparison result CMP, to enable the SAR logic 120 to output the bit B1 and generate the control signals CLK_{CP1} and CLK_{CN1}, where the switch S_{1P} may control connection of the capacitor C_{1P} (e.g. whether to connect to the reference voltage VSS or VREF) according to the control signal CLK_{CP1}, and the switch S_{1N} control connection of the capacitor C_{1N} (e.g. whether to connect to the reference voltage VSS or VREF) according to the control signal CLK_{CN1}, in order to shift voltage levels of the sampling signal VCIP and/or VCIN. The comparator 110 may compare the sampling signals VCIP and VCIN at a second rising edge of the control signal CLK_{C} to generate a second value of the comparison result CMP, to enable the SAR logic 120 to output the bit B2 and generate the control signals CLK_{CP2} and CLK_{CN2}, where the switch S_{2P} may control connection of the capacitor C_{2P} (e.g. whether to connect to the reference voltage VSS or VREF) according to the control signal CLK_{CP2}, and the switch S_{2N} may control connection of the capacitor C_{2N} (e.g. whether to connect to the reference voltage VSS or VREF) according to the control signal CLK_{CN2}, in order to shift the voltage levels of the sampling signal VCIP and/or VCIN. Deduced by analogy, after the switch S_{9P} controls connection of the capacitor C_{9P} according to the control signal CLK_{CP9} and the switch S_{9N} controls connection of the capacitor C_{9N} according to the control signal CLK_{CN9} to shift the voltage levels of the sampling signals VCIP and/or VCIN, the comparator 110 may compare the sampling signals VCIP and VCIN at a tenth rising edge of the control signal CLK_{C} to generate a tenth value of the comparison result CMP, to enable the SAR logic 120 to output the bit B10, and SAR analog-to-digital conversion is completed.

After the SAR analog-to-digital conversion mentioned above is completed, the remaining time (e.g. a period from completion of the SAR analog-to-digital conversion to the control signal CLK_{S} being pulled to the high level again) may be arranged to perform calibration of an offset of the comparator 110, where the SAR logic 120 may pull the control signal CLK_{VCM} to the high level to turn on the switch SW_{VCM}, making outputs of the comparator 110 be pulled to a same level (e.g. a level of the reference voltage VCM) for calibration of the comparator 110.

It should be noted that as the SAR ADC 10 performs calibration of the comparator 110 in the remaining time after the SAR analog-to-digital conversion is completed, the sampling period is hard to be reduced, thereby limiting an operation speed of the SAR ADC 10.

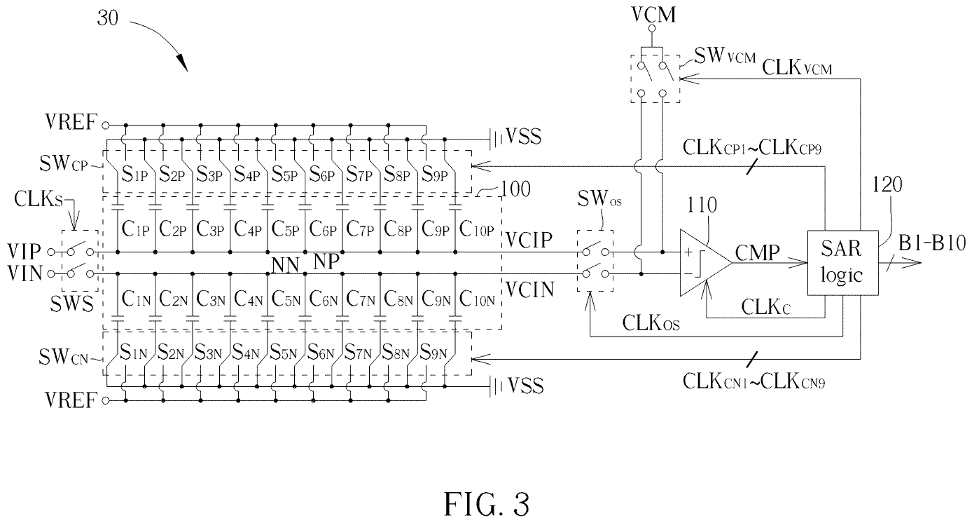

FIG. 3 is a diagram illustrating an ADC such as a SAR ADC 30 according to an embodiment of the present invention. As shown in FIG. 3, the SAR ADC 30 may comprise the sampling capacitor array 100, the comparator 110, a control logic such as the SAR logic 120, a sampling switch such as the switch SWS, an offset calibration control switch such as a switch SW_{OS}, a calibration voltage control switch such as the switch SW_{VCM}, and SAR control switches such as the switch SW_{CP} and SW_{CN}, where the switch SW_{OS} is coupled between the sampling capacitor array 100 and the comparator 110, and the SAR logic 120 is coupled to the comparator 110. In this embodiment, the sampling capacitor array 100 is configured to sample the input signal VIP and VIN, and the comparator 110 is configured to output the comparison result CMP according to voltage levels on a first input terminal (e.g. a terminal labeled “+” in figures) and a second input terminal (e.g. a terminal labeled “−” in figures) of the comparator 110. In a sampling phase of the SAR ADC 30, the switch SW_{OS} may be turned off to prevent the first input terminal and the second input terminal of the comparator 110 from being coupled to the sampling capacitor array 100, where the first input terminal and the second input terminal of the comparator 110 are pulled to a same level, and the SAR logic 120 performs calibration of the comparator 110 according to the comparison result CMP. In a conversion phase of the SAR ADC 30, the switch SW_{OS} may be turned on to make the first input terminal and the second input terminal of the comparator 110 be coupled to the sampling capacitor array 100 (e.g. respectively coupled to the positive sampling node NP and the negative sampling node NN), and the SAR logic 120 may output an analog-to-digital conversion result of the input signals {VIP, VIN} such as the bits B1 to B10 according to the comparison result CMP. More particularly, in the conversion phase, the input signals VIP and VIN on the sampling capacitor array 100 may be switched in a SAR pattern, to allow the comparator 110 to sequentially generate multiple bits such as B1 to B10 of the analog-to-digital conversion result.

In this embodiment, the switch SW_{VCM} is coupled to the first input terminal and the second input terminal of the comparator 110. In the sampling phase, the switch SW_{VCM} may be turned on to pull the first input terminal and the second input terminal of the comparator 110 to the same level. In the conversion phase, the switch SW_{VCM} may be turned off. In particular, the switch SW_{VCM} is further coupled to the reference voltage VCM, in order to pull the first input terminal and the second input terminal of the comparator 110 to a reference level of the reference voltage VCM in the sampling phase. As mentioned above, the input signals {VIP, VIN} may be a pair of differential input signals, where the reference level of the reference voltage VCM is equal to a common mode level of the pair of differential input signals.

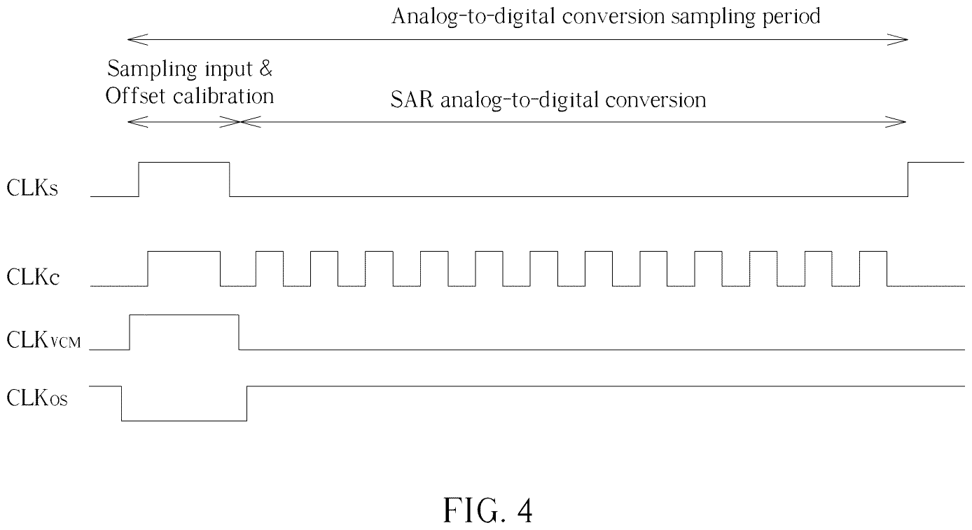

FIG. 4 is a diagram illustrating operation timing of the SAR ADC 30 shown in FIG. 3 according to an embodiment of the present invention, where the period of the control signal CLK_{S} may be regarded as a sampling period of the SAR ADC 30. In this embodiment, a period of the control signal CLK_{S} at the high level (e.g. having the logic value “1”) may be regarded as the sampling phase of the SAR ADC 30, and a period of the control signal CLK_{S} at the low level (e.g. having the logic value “0”) may be regarded as the conversion phase of the SAR ADC 30. In comparison with the operation of the SAR ADC 10, the SAR ADC 30 perform offset calibration of the comparator 110 in the sampling phase. Thus, before the control signal CLK_{S} is pulled to the high level, the control signal CLK_{OS} may be pulled to the low level to turn off the switch SW_{OS} first, in order to prevent the positive sampling node NP from being coupled to the first input terminal of the comparator 110 and prevent the positive sampling node NN from being coupled to the second input terminal of the comparator 110. Under a condition where the sampling capacitor array 100 and the comparator 110 are isolated from each other, the calibration of the comparator 110 may be performed in the sampling phase. For example, when the control signal CLK_{S} is at the high level (e.g. having the logic value “1”, the switch SWS may transmit the input signals VIP and VIN to the positive sampling node NP and the negative sampling node NN, respectively, and the switch SW_{VCM} may be turned on at this moment to pull the first input terminal and the second input terminal of the comparator 110 to the same level (e.g. the level of the reference voltage VCM) to perform the offset calibration. After the control signal CLK_{S} turns from the high level to the low level, the control signal CLK_{VCM} may be pulled to the low level to turn off the switch SW_{VCM}, and the control signal CLK_{OS} may be pulled to the high level to turn on the switch SW_{OS}, making the input signal VIP on the positive sampling node NP and the input signal VIN on the negative sampling node NN be transmitted to the first input terminal and the second input terminal of the comparator 110, respectively. The subsequent SAR analog-to-digital conversion operation is the same as the SAR ADC 10, and related details are omitted here for brevity.

It should be noted that the main feature of the present invention is to utilize the switch SW_{OS} to isolate the sampling capacitor array 100 and the comparator 110, to enable the comparator 110 perform the offset calibration un the sampling phase, and the other parts of the SAR ADC 30 (e.g. the sampling capacitor array 100, the corresponding SAR analog-to-digital conversion mechanism, and the corresponding switches such as SW_{CP} and SW_{CN}) are not limited to the implementation shown in FIG. 3.

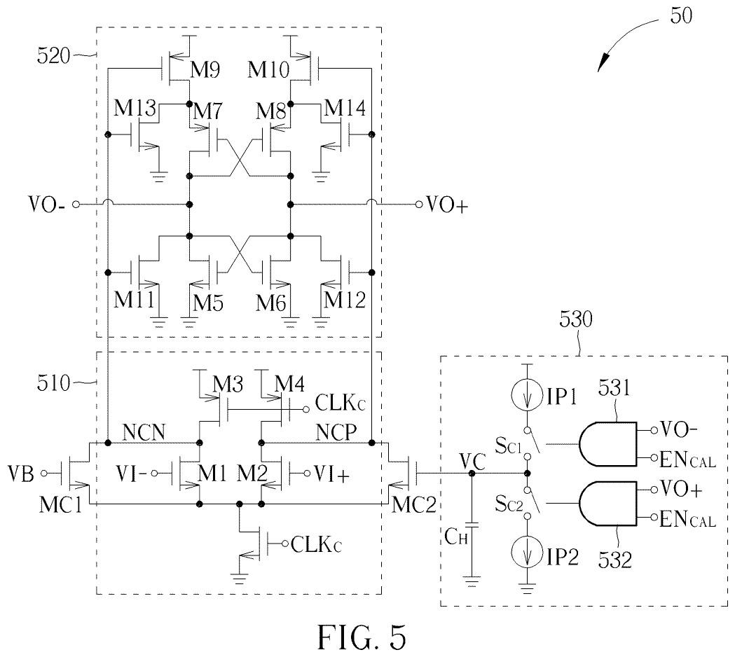

FIG. 5 is a diagram illustrating a comparator 50 according to an embodiment of the present invention, wherein the comparator 50 may be an example of the comparator 110 shown in FIG. 3. In this embodiment, the comparator 50 may comprise an input stage circuit 510, an output stage circuit 520, and at least one calibration circuit (e.g. transistors MC1 and MC2), where the output stage circuit 520 is coupled to the input stage circuit 510 via nodes NCN and NCP, and the at least one calibration circuit is coupled to at least one of the nodes NCN and NCP (e.g. the transistors MC1 and MC2 are coupled to the nodes NCN and NCP, respectively). In particular, the input stage circuit 510 is configured to generate pre-amplified signals on the nodes NCN and NCP according to a first level on a first input terminal of the comparator 50 (e.g. a level of an input voltage VI−) and a second level on a second input terminal of the comparator 50 (e.g. a level of an input voltage VI+), and the output stage circuit 520 is configured to generate the comparison result CMP according to the pre-amplified signals, where output signals VO+ or VO generated by the output stage circuit 520 may be taken as an example of the comparison result CMP. In addition, the at least one calibration circuit such as the transistors MC1 and MC2 is configured to provide a calibration load to at least one of the nodes NCN and NCP, in order to calibrate an offset of the comparator 50 (i.e. calibrating an offset voltage of the comparator 50). In this embodiment, a gate of the transistor MC1 may be controlled by a fixed voltage VB, and a gate of the transistor MC2 may be controlled by a variable voltage VC, where the comparator 50 may further comprise a voltage control circuit 530 for controlling the variable voltage VC. As shown in FIG. 5, the voltage control circuit 530 may comprise a capacitor C_{H}, switches S_{C1} and S_{C2}, current sources IP1 and IP2, AND gates 531 and 532. In the sampling phase, a calibration enable signal EN_{CAL} of the comparator 50 may be pulled to the high level, a gate voltage (i.e. the variable voltage VC) of the transistor MC2 is adjusted according to the comparison result CMP (e.g. the output signals VO+ and VO−), for example, pulling up the variable voltage VC by turning on the switch S_{C1} or pulling down the variable voltage VC by turning on the switch S_{C2}. In the conversion phase, the calibration enable signal EN_{CAL} of the comparator 50 may be pulled to the low level, making both the switches S_{C1} and S_{C2} be turned off, and the gate voltage of the transistor MC2 may be stored on the capacitor C_{H} and kept unchanged.

In this embodiment, the input stage circuit 510 may comprise transistors M1, M2, M3 and M4, and the output stage circuit 520 may comprise transistors M5, M6, M7, M8, M9, M10, M11, M12, M13 and M14, but the present invention is not limited thereto. In some embodiments, implementations of the input stage circuit 510 and the output stage circuit 520 may vary.

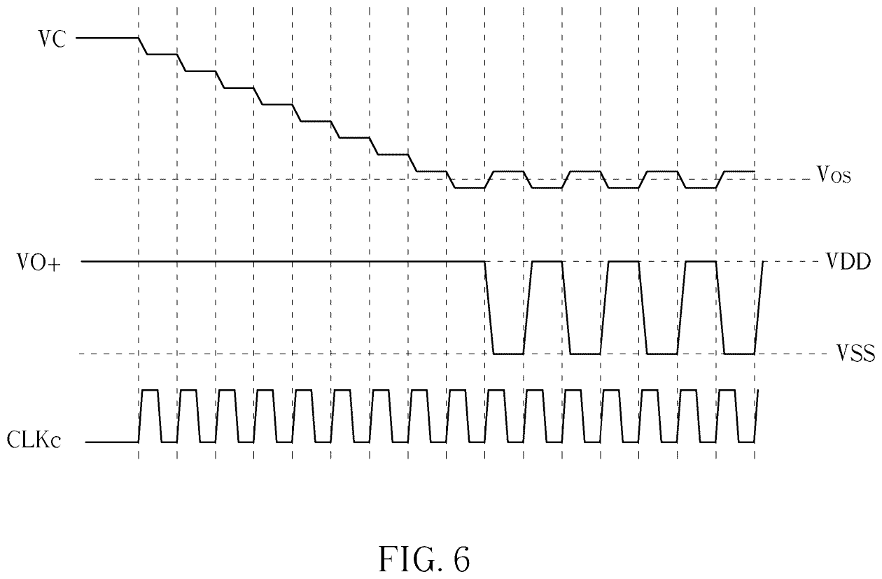

FIG. 6 is a diagram illustrating calibration of the comparator 50 shown in FIG. 5 according to an embodiment of the present invention. In this embodiment, when the output signal VO+ is at the high level (i.e. the output signal VO− is at the low level), the variable voltage VC may be pulled down. After multiple times of comparison and multiple times of adjustment of the variable voltage VC, the variable voltage VC may be adjusted to be close to an offset voltage V_{OS} of the comparator 50, where the output signal VO+ may be alternatively switched between the high level (e.g. VDD) and the low level (e.g. VSS) at this moment. It should be noted that the calibration operation of the comparator 50 (e.g. adjustment of the variable voltage VC) may be performed one time or multiple times in one sampling period. In some embodiments, the SAR ADC 30 may complete the calibration of the comparator 50 in one sampling period (e.g. making the variable voltage VC be adjusted to be close to the offset voltage V_{OS} in one sampling period). In some embodiments, the SAR ADC 30 may cost multiple sampling periods to stepwise complete calibration of the comparator 50 (e.g. costing multiple sampling periods to make the variable voltage VC be adjusted to be close to the offset voltage V_{OS}) . Those skilled in this art should understand the above modified implementations according to the embodiments of FIG. 3 to FIG. 6, and related details are omitted here for brevity.

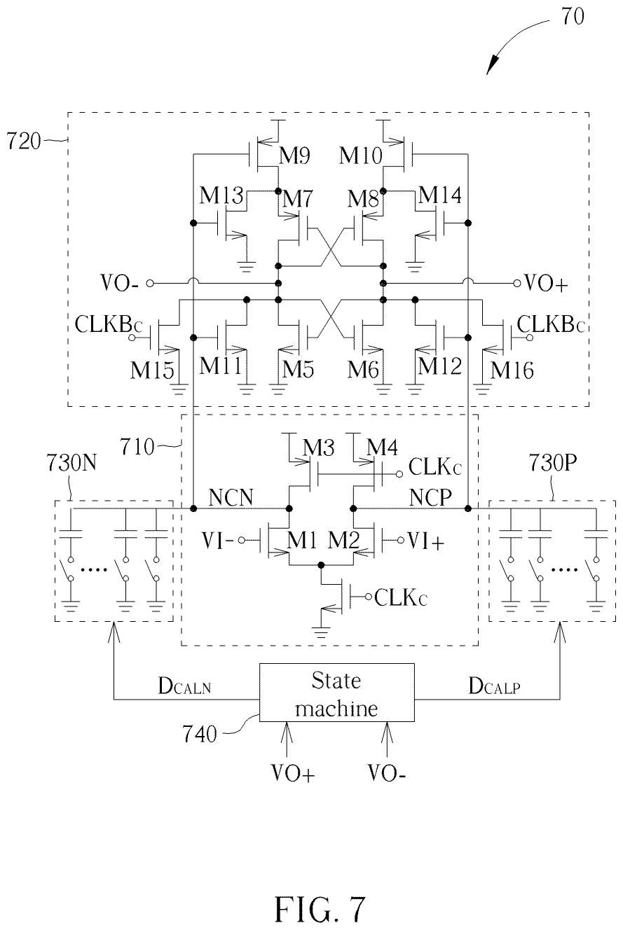

FIG. 7 is a diagram illustrating a comparator 70 according to an embodiment of the present invention, where the comparator 70 may be regarded as another example of the comparator 110 shown in FIG. 3. In this embodiment, the comparator 70 may comprise an input stage circuit 710, an input stage circuit 720, and at least one calibration circuit (e.g. calibration capacitors 730N and 730P), where the output stage circuit 720 is coupled to the input stage circuit 710 via the nodes NCN and NCP, and the at least one calibration circuit is coupled to at least one of the nodes NCN and NCP (e.g. the calibration capacitors 730N and 730P are coupled to the nodes NCN and NCP, respectively). In particular, the input stage circuit 710 is configured to generate pre-amplified signals on the nodes NCN and NCP according to a first level on a first input terminal of the comparator 70 (e.g. the level of the input voltage VI−) and a second level on a second input terminal of the comparator 70 (e.g. the level of the input voltage VI+), and the output stage circuit 720 is configured to generate the comparison result CMP according to the pre-amplified signals, where the output signals VO+ or VO− generated by the output stage circuit 720 may be taken as an example of the comparison result CMP In addition, the at least one calibration circuit such as the calibration capacitors 730N and 730P is configured to provide a calibration load to the at least one of the nodes NCN and NCP, in order to calibrate an offset of the comparator 70. In this embodiment, each of the calibration capacitors 730N and 730P may be implemented with a switchable capacitor, where capacitances of the calibration capacitors 730N and 730P may be controlled by calibration signals D_{CALN} and D_{CALP}, and the calibration signals D_{CALN} and D_{CALP} may be generated by a state machine 740 according to the comparison result CMP (e.g. the output signals VO+ and/or VO−). In some embodiments, the state machine 740 may be a part of the comparator 70. In some embodiments, the state machine 740 may be a part of the SAR logic 120. In the sampling phase, the capacitances of the calibration capacitors 730N and 730P is adjusted according to the comparison result CMP (e.g. the output signals VO+ and/or VO−). For example, the state machine 740 may increase the capacitance of the calibration capacitor 730N and reduce the capacitance of the calibration capacitor 730P according to the comparison result CMP (e.g. the output signals VO+ and/or VO−), or reduce the capacitance of the calibration capacitor 730N and increase the capacitance of the calibration capacitor 730P according to the comparison result CMP (e.g. the output signal VO+ and/or VO−). In the conversion phase, the capacitances of the calibration capacitors 730N and 730P may be kept unchanged.

In this embodiment, the input stage circuit 710 is the same as the input stage circuit 510, and related details are not repeated here for brevity. In addition to the transistors M5 to M14, the output stage circuit 520 may further comprise transistors M15 and M16 which are controlled by a control signal CLKB_{C} (e.g. an inverted signal of the control signal CLK_{C}), but the present invention is not limited thereto. In some embodiments, implementations of the input stage circuit 710 and the output stage circuit 720 may vary.

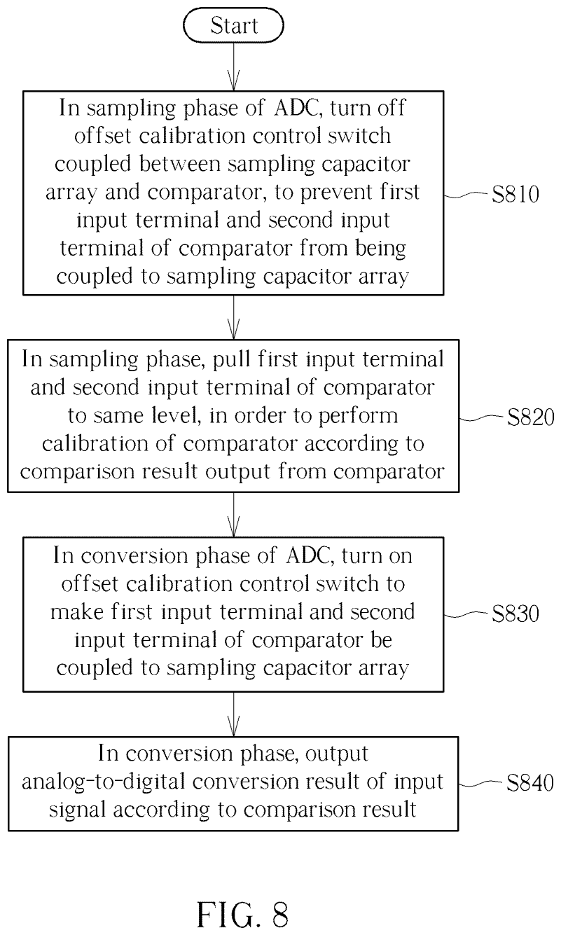

FIG. 8 is a diagram illustrating a working flow of a method for calibrating a comparator within an ADC (e.g. the SAR ADC 30 shown in FIG. 3) according to an embodiment of the present invention. It should be noted that the working flow shown in FIG. 8 is for illustrative purposes only, and is not meant to be a limitation of the present invention. For example, one or more steps may be added, deleted or modified in the working flow shown in FIG. 8. In addition, if a same result can be obtained, these steps do not have to be executed in the exact order shown in FIG. 8.

In Step S810, in a sampling phase of the ADC, the ADC may turn off an offset calibration control switch coupled between a sampling capacitor array and the comparator, to prevent a first input terminal and a second input terminal of the comparator from being coupled to the sampling capacitor array.

In Step S820, in the sampling phase, the ADC may pull the first input terminal and the second input terminal of the comparator to a same level, in order to perform calibration of the comparator according to a comparison result output from the comparator.

In Step S830, in a conversion phase of the ADC, the ADC may turn on the offset calibration control switch to make the first input terminal and the second input terminal of the comparator be coupled to the sampling capacitor array.

In Step S840, in the conversion phase, the ADC may output an analog-to-digital conversion result of the input signal according to the comparison result.

In summary, the ADC (e.g. the SAR ADC 30) and the method provided by the embodiments of the present invention can utilize the offset calibration control switch (e.g. the switch SW_{OS}) to isolated the sampling capacitor array (e.g. the sampling capacitor array 100) and the comparator (e.g. the comparator 110), to enable the comparator to be calibrated in the sampling phase, thereby preventing tasks of the ADC from being suspended. In addition, calibration of the comparator will not be the main factor affecting the operation speed of the ADC. Thus, the present invention can solve the problem of the related art without introducing any side effect or in a way that is less likely to introduce side effects.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An analog-to-digital converter (ADC), comprising:
a sampling capacitor array, configured to sample an input signal;
a comparator, configured to output a comparison result according to voltage levels on a first input terminal and a second input terminal of the comparator;
an offset calibration control switch, coupled between the sampling capacitor array and the comparator; and
a control logic, coupled to the comparator;
wherein:
in a sampling phase of the ADC, the offset calibration control switch is turned off to prevent the first input terminal and the second input terminal of the comparator from being coupled to the sampling capacitor array, the first input terminal and the second input terminal of the comparator are pulled to a same level, and the control logic performs calibration of the comparator according to the comparison result; and
in a conversion phase of the ADC, the offset calibration control switch is turned on to make the first input terminal and the second input terminal of the comparator be coupled to the sampling capacitor array, and the control logic outputs an analog-to-digital conversion result of the input signal according to the comparison result.

2. The ADC of claim 1, further comprising:
a calibration voltage control switch, coupled to the first input terminal and the second input terminal of the comparator;
wherein in the sampling phase, the calibration voltage control switch is turned on to pull the first input terminal and the second input terminal of the comparator to the same level; and in the conversion phase, the calibration voltage control switch is turned off.

3. The ADC of claim 2, wherein the calibration voltage control switch is further coupled to a reference voltage, in order to pull the first input terminal and the second input terminal of the comparator to a reference level of the reference voltage in the sampling phase.

4. The ADC of claim 3, wherein the input signal is a pair of differential input signals, and the reference level is equal to a common mode level of the pair of differential input signals.

5. The ADC of claim 1, wherein the comparator comprises:
an input stage circuit, configured to generate a pre-amplified signal according to a first level on the first input terminal of the comparator and a second level on the second input terminal of the comparator;
an output stage circuit, coupled to the input stage circuit via a first node and a second node, configured to generate the comparison result according to the pre-amplified signal; and
at least one calibration circuit, coupled to at least one of the first node and the second node, configured to provide a calibration load to the at least one of the first node and the second node, in order to calibrate an offset voltage of the comparator.

6. The ADC of claim 5, wherein the at least one calibration circuit comprises:
a calibration transistor, coupled to the at least one of the first node and the second node, wherein:
in the sampling phase, a gate voltage of the calibration transistor is adjusted according to the comparison result; and
in the conversion phase, the gate voltage of the calibration transistor is kept unchanged.

7. The ADC of claim 5, wherein the at least one calibration circuit comprises:
a calibration capacitor, coupled to the at least one of the first node and the second node, wherein:
in the sampling phase, a capacitance of the calibration capacitor is adjusted according to the comparison result; and
in the conversion phase, the capacitance of the calibration capacitor is kept unchanged.

8. The ADC of claim 1, wherein in the conversion phase, the input signal on the sampling capacitor array is switched in a successive approximation register (SAR) pattern, to allow the comparator to sequentially generate multiple bits of the analog-to-digital conversion result.

9. A method for calibrating a comparator within an analog-to-digital converter (ADC), comprising:
in a sampling phase of the ADC, turning off an offset calibration control switch coupled between a sampling capacitor array and the comparator, to prevent a first input terminal and a second input terminal of the comparator from being coupled to the sampling capacitor array;
in the sampling phase, pulling the first input terminal and the second input terminal of the comparator to a same level, in order to perform calibration of the comparator according to a comparison result output from the comparator;
in a conversion phase of the ADC, turning on the offset calibration control switch to make the first input terminal and the second input terminal of the comparator be coupled to the sampling capacitor array; and
in the conversion phase, outputting an analog-to-digital conversion result of the input signal according to the comparison result.

10. The method of claim 9, further comprising:
in the sampling phase, turning on a calibration voltage control switch coupled to the first input terminal and the second input terminal of the comparator, to pull the first input terminal and the second input terminal of the comparator to the same level; and
in the conversion phase, turning off the calibration voltage control switch.

11. The method of claim 10, wherein the calibration voltage control switch is further coupled to a reference voltage, and turning on the calibration voltage control switch to pull the first input terminal and the second input terminal of the comparator to the same level comprises:
pulling the first input terminal and the second input terminal of the comparator to a reference level of the reference voltage in the sampling phase.

12. The method of claim 11, wherein the input signal is a pair of differential input signals, and the reference level is equal to a common mode level of the pair of differential input signals.

13. The method of claim 9, wherein the comparator comprises:
an input stage circuit, configured to generate a pre-amplified signal according to a first level on the first input terminal of the comparator and a second level on the second input terminal of the comparator;
an output stage circuit, coupled to the input stage circuit via a first node and a second node, configured to generate the comparison result according to the pre-amplified signal; and
at least one calibration circuit, coupled to at least one of the first node and the second node, configured to provide a calibration load to the at least one of the first node and the second node, in order to calibrate an offset voltage of the comparator.

14. The method of claim 13, wherein the at least one calibration circuit comprises:
a calibration transistor, coupled to the at least one of the first node and the second node, wherein the method further comprises:
in the sampling phase, adjusting a gate voltage of the calibration transistor according to the comparison result; and
in the conversion phase, keeping the gate voltage of the calibration transistor unchanged.

15. The method of claim 13, wherein the at least one calibration circuit comprises:
a calibration capacitor, coupled to the at least one of the first node and the second node, wherein the method further comprises:
in the sampling phase, adjusting a capacitance of the calibration capacitor according to the comparison result; and
in the conversion phase, keeping the capacitance of the calibration capacitor unchanged.

16. The method of claim 9, wherein in the conversion phase, the input signal on the sampling capacitor array is switched in a successive approximation register (SAR) pattern, to allow the comparator to sequentially generate multiple bits of the analog-to-digital conversion result.
